(19) United States
(12) Patent Application Publication
(10) Pub. No.: US 2021/0217173 A1
(43) Pub. Date: Jul. 15, 2021

(54) NORMALIZATION AND ENHANCEMENT OF MRI BRAIN IMAGES USING MULTISCALE FILTERING

(71) Applicants: Krishna Prasad Agara Venkatesha Rao, Bengaluru (IN); Srinidhi Srinivasa, Bengaluru (IN); Ritesh Mahajan, Cupertino, CA (US); Sanjib Sinha, Cupertino, CA (US); Mariyappa Narayanan, Cupertino, CA (US); Bhargava Gautham, Cupertino, CA (US); Jitender Saini, Cupertino, CA (US)

(72) Inventors: Krishna Prasad Agara Venkatesha Rao, Bengaluru (IN); Srinidhi Srinivasa, Bengaluru (IN); Ritesh Mahajan, Cupertino, CA (US); Sanjib Sinha, Cupertino, CA (US); Mariyappa Narayanan, Cupertino, CA (US); Bhargava Gautham, Cupertino, CA (US); Jitender Saini, Cupertino, CA (US)

(73) Assignee: Ricoh Company, Ltd., Tokyo (JP)

(21) Appl. No.: 16/744,081

(22) Filed: Jan. 15, 2020

(51) Int. Cl. G06T 7/00; G01R 33/56; G01R 33/565

(52) U.S. Cl. CPC G06T 7/0016; G01R 33/5608; G06T 2207/30016; G06T 2207/10088; G01R 33/56572

(57) ABSTRACT

In one aspect, multiscale filtering is used to normalize the intensities of voxels in an MRI image. A multiscale filter is applied to the raw MRI image. This image is compared to the original image. Luma aberrations (i.e., intensity variations) are corrected based on this comparison. In one approach, the intensity of the image is increased for voxels that are dimmer than in the multiscale filtered version, and decreased for voxels that are brighter than the multiscale filtered version. In another aspect, additional features are created based on multiscale gradients. These may be used in combination with other approaches to segment the MRI image. Voxels with positive gradients may represent brain gray matter bordered by brain white matter. Voxels with negative gradients may represent brain white matter bordered by brain grain matter.

### BACKGROUND

### 1. Technical Field

This disclosure relates generally to brain segmentation of MRI images

### 2. Description of Related Art

Segmentation is one step in the analysis of MRI (magnetic resonance imaging) images of brains. A three-dimensional MRI image of a brain typically is a three-dimensional array of voxels, where each voxel has a value (intensity) that represents the response of the matter in that voxel to the MRI imaging process. The segmentation step determines which of the voxels are brain matter and which are not. After the MRI image has been segmented, the voxels that are brain matter may then be further analyzed.

Segmentation typically is often performed based on the intensity of voxels in the MRI image. For example, in one approach, clusters of similar intensity voxels are grouped, on the assumption that similar intensity voxels represent the same type of matter. However, this is not always a good assumption.

For example, noise and intensity variations in the MRI imaging process may lead to erroneous results. Bias field variance may lead to less intense voxels on one side of the MRI image compared to the other, even for the same type of brain matter. In addition, different physiological regions may have voxels of similar intensity, and clustering voxels based on intensity would not distinguish between these different regions. For example, brain gray matter is less intense than brain white matter, but it may be similar in intensity to non-brain structures. Clustering based on intensity alone may not successfully segment the brain gray matter.

Thus, there is a need for better approaches for brain segmentation of MRI images.

### SUMMARY

In one aspect, multiscale filtering is used to normalize the intensities of voxels in an MRI image. A multiscale filter is applied to an MM image. A multiscale filter applies filters of different scales (e.g., using kernels of different sizes) to the image. In one approach, a 1×1×1 filter, a 3×3×3 filter, a 5×5×5 filter, etc. are applied and a weighted sum of these component filtered images is calculated to produce the multiscale filtered image. Luma aberrations (i.e., intensity variations) are corrected based on the comparison of the multiscale filtered image to the original image. In one approach, the intensity of the image is increased for voxels in the original image that are dimmer than in the multiscale filtered version and decreased for voxels that are brighter than the multiscale filtered version.

In another aspect, additional features are created based on multiscale gradients. These may be used in combination with other features to segment the MRI image. An MRI image is filtered using filters of different scales k. The gradient with respect to k is calculated. For each voxel, this is the variation in intensity of that voxel with respect to k. Voxels with positive gradients may represent brain gray matter bordered by brain white matter. Voxels with negative gradients may represent brain white matter bordered by brain grain matter.

The two techniques may be combined. Normalization may first be applied to an MRI image. Multiscale gradients for the normalized version may then be calculated.

Other aspects include components, devices, systems, improvements, methods, processes, applications, computer readable mediums, and other technologies related to any of the above.

### BRIEF DESCRIPTION OF THE DRAWINGS

Embodiments of the disclosure have other advantages and features which will be more readily apparent from the following detailed description and the appended claims, when taken in conjunction with the examples in the accompanying drawings, in which:

FIG. 1 is a flow diagram for volume intensity normalization of an MRI image, according to one embodiment.

FIG. 2 (prior art) is one slice of a three-dimensional MM image.

FIG. 3A shows multiscale filtering using kernels of different sizes.

FIG. 3B shows multiscale filtering using kernels of different widths.

FIG. 4 is one slice of a head mask for the MRI image of FIG. 2.

FIG. 5 is a flow diagram illustrating multiscale gradient features, according to one embodiment.

FIG. 6A is a slice of an MM image showing gray matter bordered by white matter.

FIG. 6B is a graph of intensity as a function of scale k.

### DETAILED DESCRIPTION OF THE PREFERRED EMBODIMENTS

The figures and the following description relate to preferred embodiments by way of illustration only. It should be noted that from the following discussion, alternative embodiments of the structures and methods disclosed herein will be readily recognized as viable alternatives that may be employed without departing from the principles of what is claimed.

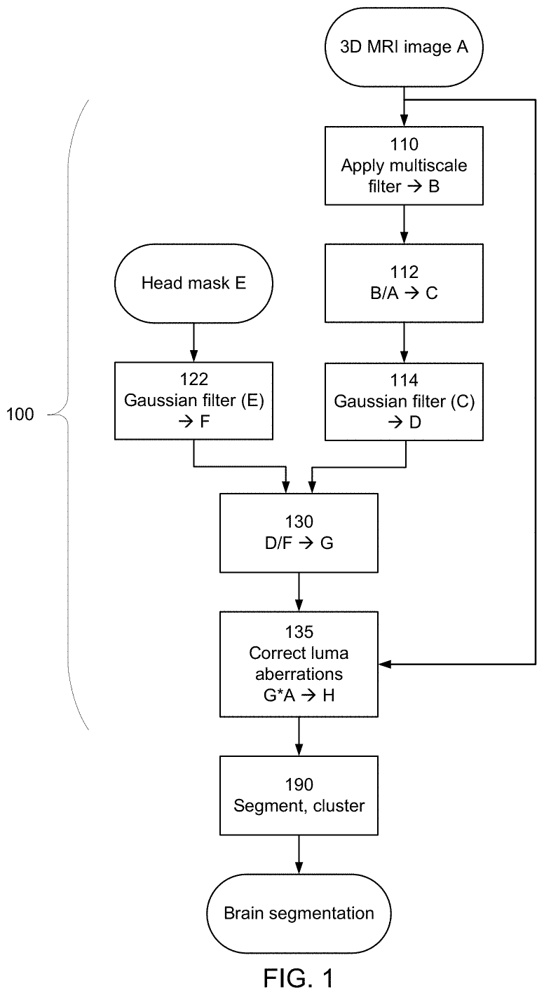

FIG. 1 is a flow diagram for volume intensity normalization 100 of an MRI image, according to one embodiment. The process begins with a three-dimensional MRI image A of the head or a part of the head. Typically, the image A is represented by a three-dimensional array of voxels. In the following example, assume that A is a 256×256×256 array of voxels. The nomenclature A(x) will be used to represent the individual voxels of image A. The x is an indexing of the voxels, and A(x) is the intensity of voxel x.

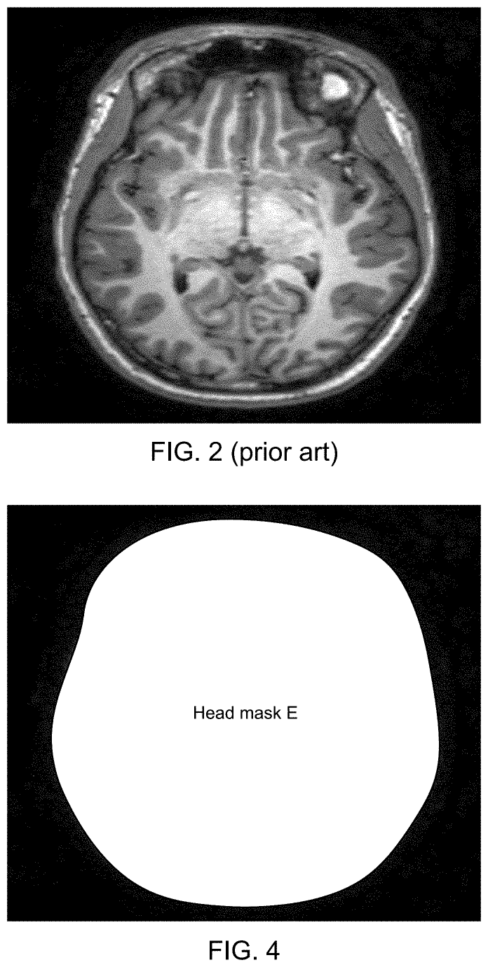

FIG. 2 (prior art) shows one slice of a three-dimensional MRI image of the head. In this example, each voxel x has a value (intensity) A(x) that represents the response of the matter in that voxel to the MRI imaging process. The intensity values are shown by grayscale in FIG. 2, ranging from black to white. The MRI image A includes brain matter but may also include non-brain matter, for example eyes, nasal cavity, skull, muscles, etc. Image A may also have intensity anomalies (luma aberrations), for example caused by noise or systematic biases.

The process 100 of FIG. 1 corrects for luma aberrations, yielding a normalized image H. The normalized image H may then be used in a segmentation process 190, which identifies which of the voxels are brain matter. A properly normalized image H will yield more accurate results compared to segmentation based on the raw image A.

Process 100 proceeds as follows. A multiscale filter 110 is applied to the input image A, producing the filtered image B. In one approach, the multiscale filter 110 uses filters Fₖ of different scales, where k is the index for scale. The input image A is filtered by each filter Fₖ to produce a component filtered image Bₖ, and a weighted sum of the Bₖ yields the aggregate filtered image B. Mathematically,

B=Σₖwₖ*Bₖ (1)
where Bₖ=A**Fₖ
   wₖ are weights, the summation is over the different scales k, * is multiplication, and ** is convolution.

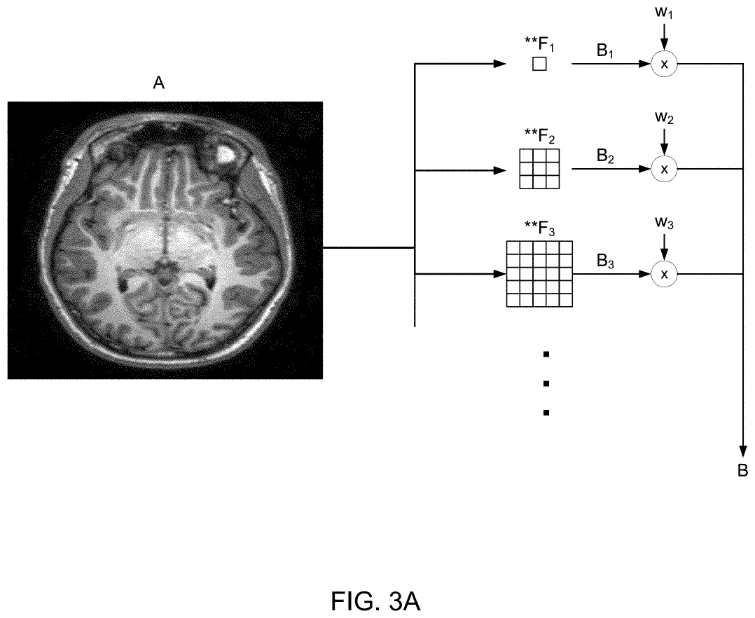

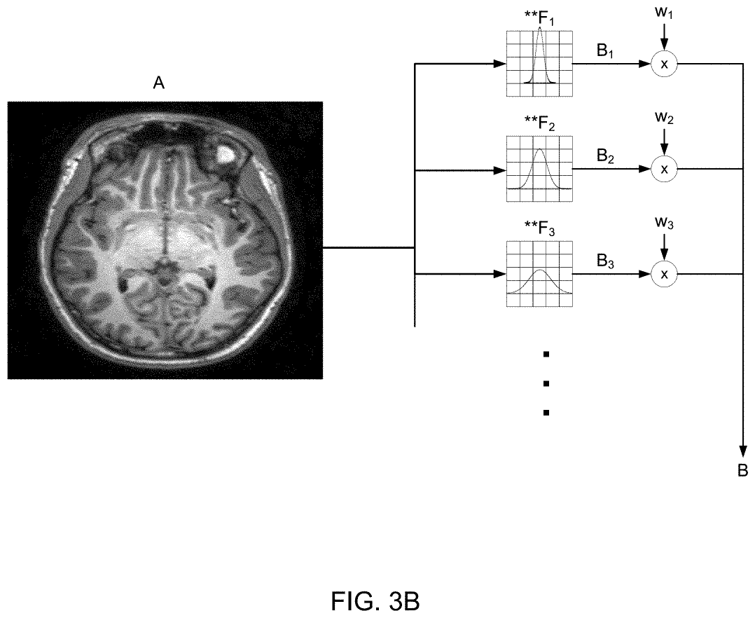

The different scale filters Fₖ may take different forms. FIG. 3A shows multiscale filtering using kernels of different sizes. Filter F₁ has a kernel size of 1×1, filter F₂ has a kernel size of 3×3, filter F₃ has a kernel size of 5×5, etc. For convenience of illustration, two-dimensional filtering is shown in FIG. 3A, but the multiscale filtering could involve any number of dimensions. Image A is convolved with each of the different size filters Fₖ. The filtered images are weighted and summed to produce the multiscale filtered version B.

FIG. 3B shows multiscale filtering using kernels of the same size but different widths. Here, all the kernels are 5×5, but they represent Gaussians of different widths, as shown by the Gaussian curves for each filter. Filter F₁ is the narrowest Gaussian, filter F₂ is wider, filter F₃ is even wider, etc.

Multiscale filtering does not have to be based on convolution. Space-invariant filtering may be used, for example. If the scale is implemented by filters of different sizes, then each component image Bₖ for a voxel x will be based on the intensity values of voxels within a certain neighborhood of x, where the size of the neighborhood varies with the scale k.

Because image B is the multiscale filtered version of image A, B(x) represents some sort of “average” intensity in the local neighborhood of voxel x while A(x) is the intensity of just voxel x. In the rest of process 100, the images A and B are compared, and the intensity of image A is corrected for luma aberrations based on this comparison.

Returning to FIG. 1, the ratio C=B/A is calculated 112. Here, the division is voxel-based. That is, for each voxel x, C(x)=B(x)/A(x). If B(x)>A(x), or equivalently if C(x)>1, then voxel x has lower intensity than the neighborhood average and the intensity of voxel A(x) should be increased if this is an anomaly. Conversely, if B(x)<A(x) or C(x)<1, then voxel x has lower intensity than the neighborhood average and the intensity of voxel A(x) should be increased. In FIG. 1, the ratio C is filtered 114 by a Gaussian filter to produce the filtered ratio D. This smooths out the ratio C so that the normalization effects are not too extreme.

In FIG. 1, a head mask E is also used to constrain the effects of normalization. FIG. 4 is one slice of a head mask E, corresponding to the MM image of FIG. 2. The head mask is 1 (shown as white in FIG. 4) for voxels that are part of the head and 0 (black in FIG. 4) for voxels outside the head. The head mask E is also filtered 122 by a Gaussian filter to smooth the boundary between head and no head, producing a smoothed head mask F. This is applied 130 to the filtered ratio D, yielding the normalization mask G=D/F, where the division is voxel-based and performed only for voxels that are within the head volume.

The normalization mask G is then applied 135 to the original image A to yield the luma-corrected image H=G*A where the multiplication is voxel-based. That is, H(x)=G(x)*A(x).

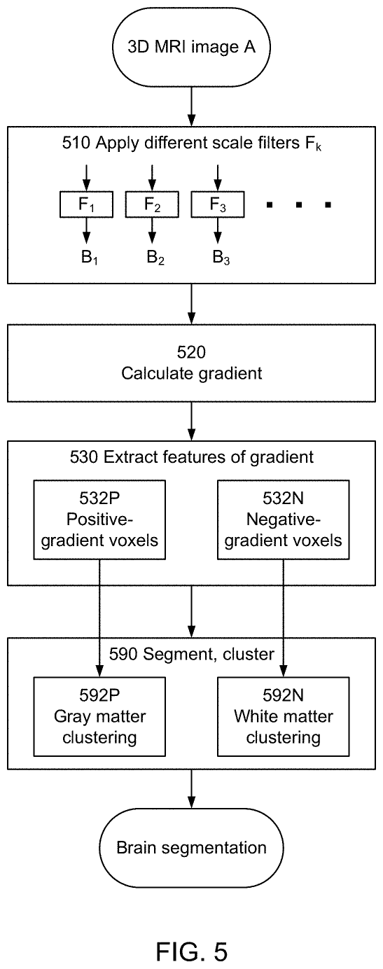

In a different aspect, FIG. 5 is a flow diagram illustrating multiscale gradient features, according to one embodiment. Multiscale gradient features are features based on the gradient of intensity with respect to scale. The process begins with a three-dimensional MRI image A of the head or a part of the head. This could be the same image A as in FIG. 1 or it could be a different image, such as the normalized image H in FIG. 1. Multiple filters Fₖ of different scales k are applied 510 to the input image A to produce filtered images Bₖ, where k is the index or dimension for scale. The different scale filters Fₖ described above with respect to process 100 may also be used here. Each filtered image Bₖ is an array of voxels x, where Bₖ(x) is the intensity of voxel x at scale k. Note that Bₖ(x) is a function of x, but it is also a function of the scale k. The gradient with respect to k is calculated 520. This may be done by taking the difference ΔBₖ(x)=Bₖ₊₁(x)−Bₖ(x), or using the difference ΔBₖ(x) normalized by the “distance” between scales (k+1) and (k). Alternatively, numerical methods may be used to estimate the derivative ∂Bₖ(x)/∂k. Features 530 of the gradient may be extracted and used in the process of brain segmentation 590.

FIG. 5 also shows a specific example. In this example, the features 530 include voxels 532P that have positive gradients and voxels 532N that have negative gradients. Clustering algorithms are applied 592 to MRI image to segment the brain, but the white matter and gray matter are considered separately. The positive-gradient voxels 532P are included as part of the gray matter clustering 592P. The negative-gradient voxels 532N are included as part of the white matter clustering 592N.

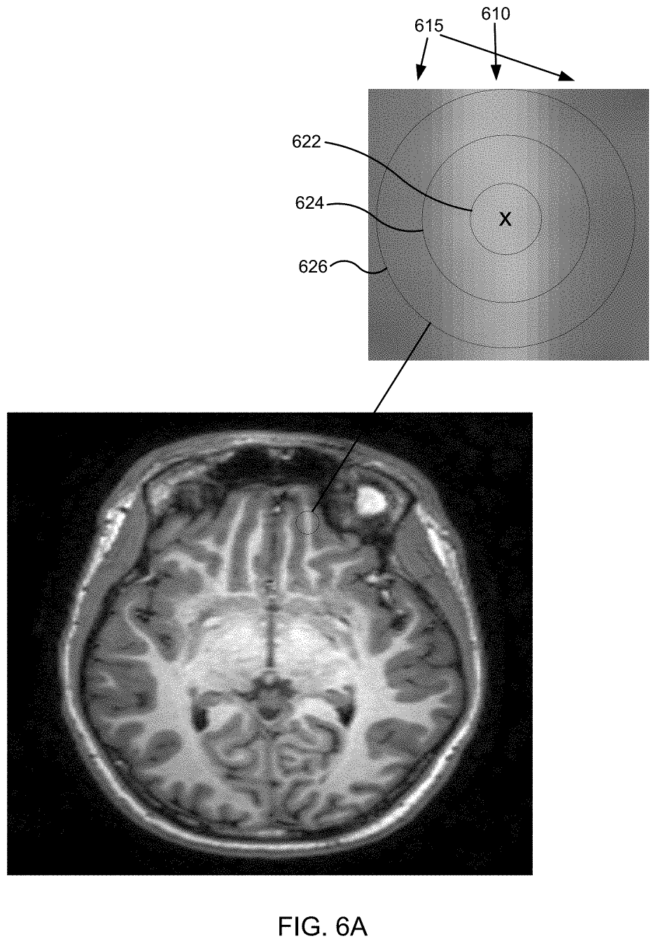

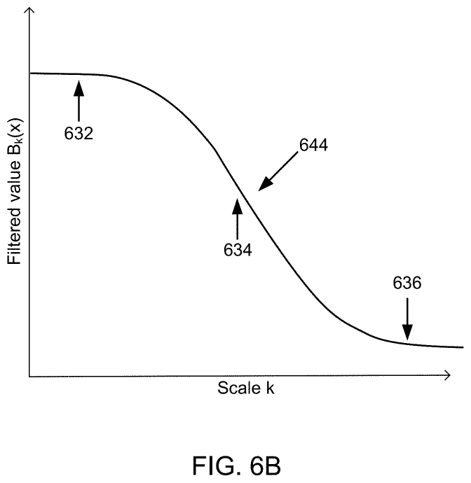

FIG. 6A is a slice of an MRI image. The circled region is a magnification of an area with white matter bordered by gray matter. The white matter 610 has higher intensity and the surrounding gray matter 615 has lower intensity. FIG. 6B is a graph of intensity as a function of scale k for a voxel x in the white matter volume. At small scales k, the filtering includes only those voxels in a small neighborhood 622 around voxel x, which is mostly white matter voxels. Therefore, the filtered intensity Bₖ(x) 632 at small values of k is fairly constant at the higher intensity level for white matter. As the scale k increases, the neighborhood 624 increases to include surrounding gray matter and the filtered intensity Bₖ(x) 634 decreases, so there is a negative gradient 644. If the gray matter is large in volume, then at large scales 626, the filtered value Bₖ(x) 636 will begin to saturate. Thus, the negative gradient 644 is in indication of white matter bordered by gray matter, and the corresponding scale k is an indication of the width of the white matter.

An analogous situation occurs for gray matter bordered by white matter. When the scale is small, the voxels in the neighborhood are mostly gray matter so the filtered intensity remains lower. As the neighborhood increases in size, more white matter voxels are included. The filtered intensity increases, and there is a positive gradient of intensity with respect to scale k.

Thus, positive-gradient voxels and negative-gradient voxels and their corresponding scales k may be used as additional features for segmenting an MRI image into brain matter and not brain matter, or into gray and white brain matter.

Although the detailed description contains many specifics, these should not be construed as limiting the scope of the invention but merely as illustrating different examples. It should be appreciated that the scope of the disclosure includes other embodiments not discussed in detail above. Various other modifications, changes and variations which will be apparent to those skilled in the art may be made in the arrangement, operation and details of the method and apparatus disclosed herein without departing from the spirit and scope as defined in the appended claims. Therefore, the scope of the invention should be determined by the appended claims and their legal equivalents.

Alternate embodiments are implemented in computer hardware, firmware, software, and/or combinations thereof. Implementations can be implemented in a computer program product tangibly embodied in a computer-readable storage device for execution by a programmable processor; and method steps can be performed by a programmable processor executing a program of instructions to perform functions by operating on input data and generating output. Embodiments can be implemented advantageously in one or more computer programs that are executable on a programmable computer system including at least one programmable processor coupled to receive data and instructions from, and to transmit data and instructions to, a data storage system, at least one input device, and at least one output device. Each computer program can be implemented in a high-level procedural or object-oriented programming language, or in assembly or machine language if desired; and in any case, the language can be a compiled or interpreted language. Suitable processors include, by way of example, both general and special purpose microprocessors. Generally, a processor will receive instructions and data from a read-only memory and/or a random access memory. Generally, a computer will include one or more mass storage devices for storing data files; such devices include magnetic disks, such as internal hard disks and removable disks; magneto-optical disks; and optical disks. Storage devices suitable for tangibly embodying computer program instructions and data include all forms of non-volatile memory, including by way of example semiconductor memory devices, such as EPROM, EEPROM, and flash memory devices; magnetic disks such as internal hard disks and removable disks; magneto-optical disks; and CD-ROM disks. Any of the foregoing can be supplemented by, or incorporated in, ASICs (application-specific integrated circuits), FPGAs and other forms of hardware.

What is claimed is:

1. A method for processing a three-dimensional MRI image A of voxels that includes brain matter, the method implemented on a computer system executing instructions comprising:
applying a multiscale filter to image A to produce an image B;
comparing images A and B;
correcting for luma aberrations in image A, based on the comparison of images A and B; and
segmenting brain matter based on the luma-corrected version of image A.

2. The computer-implemented method of claim 1 wherein applying the multiscale filter to image A comprises:
applying a plurality of filters of different scales k to image A; and
calculating a weighted sum of the filtered images of A.

3. The computer-implemented method of claim 2 wherein the filters of different scales k comprise filters with kernels of different sizes.

4. The computer-implemented method of claim 2 wherein the filters of different scales k comprise filters with kernels of a same size but different widths.

5. The computer-implemented method of claim 1 wherein comparing images A and B comprises:
calculating a ratio C=B/A, where the division is performed on a voxel basis.

6. The computer-implemented method of claim 5 wherein correcting for luma aberrations in image A comprises:
increasing the intensity of voxels with C>1.

7. The computer-implemented method of claim 5 wherein correcting for luma aberrations in image A comprises:
decreasing the intensity of voxels with C<1.

8. The computer-implemented method of claim 5 wherein comparing images A and B further comprises:
applying a Gaussian filter to ratio C to produce filtered ratio D, wherein correcting for luma aberrations in image A is based on filtered ratio D.

9. The computer-implemented method of claim 1 wherein comparing images A and B identifies voxels in image A with intensity that is inconsistent with the neighboring voxels.

10. The computer-implemented method of claim 1 wherein correcting for luma aberrations in image A further comprises:
applying a Gaussian filter to a head mask E to produce a filtered head mask F, wherein the head mask E labels voxels in image A that have been identified as part of a head; and
correcting for luma aberrations based on the filtered head mask F.

11. A method for processing a three-dimensional MRI image A of voxels that includes brain matter, the method implemented on a computer system executing instructions comprising:
applying a plurality of filters with kernels of different sizes to image A;
calculating a weighted sum of the filtered images of A to produce an image B;
calculating a ratio C=A/B, where the division is performed on a voxel basis;
applying a Gaussian filter to ratio C to produce filtered ratio D;
applying a Gaussian filter to a head mask E to produce a filtered head mask F, wherein the head mask E labels voxels in image A that have been identified as part of a head;
calculating a normalization mask G=D/F, where the division is performed on a voxel basis;
correcting for luma aberrations in image A, based on the normalization mask G; and
segmenting brain matter, based on the luma-corrected version of image A.

12. A method for processing a three-dimensional MRI image A of voxels that includes brain matter, the method implemented on a computer system executing instructions comprising:
applying a plurality of filters of different scales k to image A to produce a plurality of images Bₖ;
calculating a gradient for voxels of B with respect to scale k;
identifying voxels with a positive gradient and voxels with a negative gradient; and
segmenting brain matter from the image A, based on the positive-gradient voxels and/or the negative-gradient voxels.

13. The computer-implemented method of claim 12 wherein the filters of different scales k comprise filters with kernels of different sizes.

14. The computer-implemented method of claim 12 wherein segmenting brain matter from the image A comprises separately segmenting brain white matter and brain gray matter from the image A.

15. The computer-implemented method of claim 14 wherein segmenting the brain gray matter is based on positive-gradient voxels.

16. The computer-implemented method of claim 14 wherein segmenting the brain white matter is based on negative-gradient voxels.

17. The computer-implemented method of claim 12 wherein segmenting brain matter from the image A further comprises:
clustering voxels based on their intensities.

18. The computer-implemented method of claim 12 wherein segmenting brain matter from the image A is further based on the scale k for which voxels have positive gradient and/or negative gradient.

19. The computer-implemented method of claim 12 wherein the image A is a luma-corrected image.

20. The computer-implemented method of claim 19 further comprising:
applying a multiscale filter to an uncorrected version of image A to produce an image B;
comparing the uncorrected version of image A and image B; and
correcting for luma aberrations in image A, based on the comparison of images A and B.
